(19) United States
(12) Patent Application Publication
(10) Pub. No.: US 2014/0079874 A1
(43) Pub. Date: Mar. 20, 2014

(54) METHOD AND DEVICE FOR PRINTING FUNCTIONAL LAYERS FOR ELECTRONIC COMPONENTS

(71) Applicant: HEIDELBERGER DRUCKMASCHINEN AG, HEIDELBERG (DE)

(72) Inventors: MICHAELA AGARI, HEIDELBERG (DE); GERARDO HERNANDEZ-SOSA, HEIDELBERG (DE); NORMAN MECHAU, KARLSRUHE (DE); INGO RINGLE, EPPELHEIM (DE); ANDREAS RUPPRECHT, MAUER (DE)

(73) Assignee: HEIDELBERGER DRUCKMASCHINEN AG, HEIDELBERG (DE)

(21) Appl. No.: 14/032,413

(22) Filed: Sep. 20, 2013

(30) Foreign Application Priority Data
Sep. 20, 2012 (DE) 102012018583.9

(51) Int. Cl. B41M 3/00; H01L 51/00; H05B 33/10

(52) U.S. Cl. CPC B41M 3/00; H05B 33/10; H01L 51/0038; H01L 51/0037
USPC 427/66; 427/58; 118/50; 118/642; 118/58; 252/500

(57) ABSTRACT

A method for printing fluid layers for producing functional layers for electronic components in a rotary printing machine. The drying time t_{dry}, or the time tᵢₘₘ between the printing of the fluid layer in the printing nip of cylinders of the printing machine and the immobilization of the fluid layer, and the time (x·tₗₑᵥ) after which differences in thickness in the fluid layer have subsided after printing to a residual level that is no longer problematic for the functionality of the layer, are adapted to one another. This is effected either by way of technical method-related measures after leaving the printing nip or by suitable setting of the rheology of the fluid to be printed.

### CROSS-REFERENCE TO RELATED APPLICATION

This application claims the priority, under 35 U.S.C. §119, of German patent application DE 10 2012 018 583.9, filed Sep. 20, 2012; the prior application is herewith incorporated by reference in its entirety.

### BACKGROUND OF THE INVENTION

### Field of the Invention

The invention relates to a method for printing functional layers for electronic components in a rotary printing machine. Recent years have already seen the development of various approaches to printing electronic components, such as for example antennas, RFIDs, solar cells, in particular also active devices such as organic light-emitting diodes (OLEDs), as a way of producing the devices at lower cost than is usual with the methods of production that are customary at present, such as lithography, spin coating, etc. These approaches have mainly focused on inkjet methods, because a large number of different printing fluids can be printed by way of inkjet nozzles and there is the possibility of designing the products to be printed very individually.

Thus, for example, U.S. Pat. No. 8,404,159 B2 and its counterpart international patent application publication WO 2009/109738 A1 describe a printing fluid that is suitable in particular for inkjet printing and, on the basis of the chosen combination of solvents, yields uniform layers, which are required for the production of OLEDs. The described combinations of solvents are based on solvents of a very low viscosity with a high boiling point.

U.S. Pat. No. 7,704,785 B2 and its counterpart international patent application publication WO 2005/112145 A1 in turn specify fluids for producing semiconductors that are based on the mixing of two solvents, one of which dissolves the solid semiconductor material well and the other dissolves it poorly. However, the combinations of solvents specified there are suitable primarily for the production of OLEDs by the spin coating method. Further fluids for the production of OLEDs are described for example in U.S. Pat. No. 6,878,312 B1 (EP 1083775 B1), U.S. Patent application publication US 2013/026415 A1 (WO 2011/128034 A1), U.S. Pat. No. 8,373,162 B2 (WO 2010/147818 A1) and U.S. Patent application publication US 2012/256137 A1 (WO 2011/076324 A1).

However, production only becomes particularly low in cost when the devices can be printed on a rotary printing machine by gravure, offset or flexographic printing. In the case of these methods, however, it is difficult to print printing inks of very low viscosity, that is to say inkjet inks. The fact that the transfer of the ink takes place by ink splitting in a printing nip means that it tends to be inks of a higher viscosity, which on the other hand may also contain a higher fraction of solid material, that are required, making it possible that the functional layers for the components can be printed as it were in one pass, and nevertheless the required layer thicknesses after evaporation of the solvent can be achieved.

In the case of the rotary printing methods on the ink splitting principle, however, a problem arises as a result of the substrate passing through the printing nip. The surface structure of the printing form or of the print transfer cylinder, and also effects of the ink splitting in the printing nip itself, have the consequence that the printed layers are modulated with a structure, in other words that the layer thickness is not uniform. When inks are printed onto absorbent printing materials such as paper, remaining modulations of the layer thickness in the submicrometer range are not noticeable. When they are printed onto electronic substrates, on the other hand, it is necessary to obtain planar printed layers in the range of a few nanometers (nm). If these requirements are not met, in the case of printed OLEDs, for example, there are clearly visible fluctuations in brightness. Such products would not be suitable for sale.

However, none of the prior art cited above provides any indication as to how the problem described could be solved in the production of functional layers for printed electronic substrates on rotary printing machines.

### SUMMARY OF THE INVENTION

It is accordingly an object of the invention to provide a method and a device for printing functional layers of electronic components which overcome the above-mentioned disadvantages of the heretofore-known devices and methods of this general type and which provides for a method by which electronic components of uniform layer thicknesses in the range of a few nm can be produced on rotary printing machines.

The term rotary printing machines is to be understood hereinafter as meaning those printing machines on which the substrate passes through a printing nip, in which forces are exerted on the printed fluid for the functional layers of the electronic components.

With the foregoing and other objects in view there is provided, in accordance with the invention, a method of printing fluid layers for producing functional layers for electronic components, the method comprising:

printing a fluid layer in a printing nip between cylinders of a rotary printing machine;

defining a drying time t_{dry} for the fluid, or an immobilization time tᵢₘₘ between the printing of the fluid layer in the printing nip and an immobilization of the fluid layer;

defining a demodulation time (x·tₗₑᵥ) after which differences in thickness in the fluid layer have subsided after printing to a residual modulation level that is no longer considered problematic; and

adapting the drying time t_{dry}, or the immobilization time tᵢₘₘ, and the demodulation time (x·tₗₑᵥ) to one another such that (x·tₗₑᵥ)<tᵢₘₘ or (x·tₗₑᵥ)<t_{dry}, where x is a number greater than 1.

In other words, according to the novel method, the drying time of the printed fluid layer, or the time that passes between the printing of the fluid layer and the subsequent evaporation of the solvent contained, up to the point in time at which the printed fluid layer is “immobilized”, i.e. cannot be smoothed any further by the surface tension on account of the ever-increasing viscosity of the layer, and the so-called leveling time or demodulation time tₗₑᵥ, which passes before the differences in thickness of the printed fluid layer caused by the processes in the printing nip have subsided to a no longer problematic residual level, are adapted to one another. In this case, the condition x·tₗₑᵥ<tᵢₘₘ or x·tₗₑᵥ<t_{dry} is met, where x is a number ≦1, i.e. the amplitudes of the modulations must have subsided before the increasing viscosity of the printed fluid layer prevents further smoothing in the course of the drying process.

This cannot simply be achieved by adapting the viscosity of the printing fluid, consisting of a solid material for the functional layer and a solvent, to that of inks such as those that are printed on rotary printing machines. This is so because such fluids that are mixed together without any thought being given to other considerations would dry much more quickly than they become smooth, and consequently make the functional layers produced with them unusable.

As experiments have shown, the demodulation time required for the production of usable functional layers can very well lie within the range of 10³ seconds, i.e. in the range of double-digit minutes. It can be determined experimentally or else estimated on the basis of the following formula:

$${τ}_{lev} = \frac{3 {ηλ}^{4}}{16 {π}^{4} {σ}_{T} {h}_{0}^{3}} \qquad ( 1 )$$

Here, η is the viscosity of the fluid to be printed, λ is the wavelength of the modulations that the printed fluid layer undergoes in the printing nip, σ_{T} is the surface tension and h₀ is the thickness of the printed fluid film.

The sequence on which equ. (1) is based is outlined in a simplified form in the schematic representations of FIGS. 1A to 1D. After the squeegeeing of the ink on the surface of a gravure cylinder (FIG. 1A), the fluid located in the cells of the gravure cylinder is transferred to the substrate to be printed (FIG. 1B). After leaving the printing nip, the substrate bears a layer of fluid, the surface of which is modulated with the cell structure (FIG. 1C). These modulations or inhomogeneities of the layer thickness subside only slowly in the submicrometer range (FIG. 1D). Apart from the modulations due to the surface structure, there are also modulations with a greater wavelength λ, which are caused by the ink splitting behavior in the printing nip and are attributable to the phenomena known in the literature by the designation “Saffman-Taylor instability”. It has been found that the amplitudes of these longer-wave modulations dominate inhomogeneities of the layer thickness.

In equ. (1), the term tₗₑᵥ is the time that passes until the amplitude of the modulation of the printed fluid layer has subsided to e⁻¹. Since, however, the initial amplitude of layer thickness modulations may well be of the order of magnitude of 50% of the layer thickness itself after printed layers have left the printing nip, but in the case of functional layers for printed electronic substrates the layer thickness variation must not be any more than 10% of the layer thickness itself, or below, it is necessary to meet the condition

x·tₗₑᵥ≦tᵢₘₘ (2)

where x is at least greater than 1 and is typically a number >2.

The condition (2) can be met on the one hand by the immobilization time tᵢₘₘ being set appropriately, i.e. extended, by technical method-related measures in the course of the process after the printing of the fluid layers onto the substrate. This can be achieved by providing that, after the substrate has left the printing nip of the rotary printing machine, the printed functional layers are fed to a drying zone, in which the functional layer dries with a low rate of evaporation of the solvent or solvent mixture, or are exposed to a solvent atmosphere in this “drying zone”, or rather treatment zone, so that they do not dry at all during this time, and are fed to a dryer after that, i.e. only after the required demodulation time has elapsed. Thus, the printed fluid layer has time to become smooth before it is then completely immobilized and/or dried or hardened in the dryer, and if appropriate in a further step the last remaining problematic residues of the solvents are outgassed from the functional layer in a vacuum chamber.

As an alternative to the technical process-related or method-related measure, it is also possible, and generally also advantageous in combination with the aforementioned measure, if the adaptation of the demodulation time and immobilization time, in the sense of a shortening of the demodulation time and lengthening of the immobilization time, by way of the rheology of the fluid to be printed is performed even before the printing of the fluid layer onto the substrate. This can be achieved by various parameters, such as suitable selection of a solvent or solvent mixture, if appropriate the mixing ratio of the two or more solvents and/or the concentration of the solid material in the fluid to be printed that forms the functional layer in the dried state, etc., expediently by ensuring by appropriate choice of the parameters mentioned that the viscosity of the fluid to be printed only has a low dependence on the shear rate. This is so because then the viscosity scarcely increases after the fluid leaves the printing nip, in the then following unsheared state thereof, and is primarily increased only by the evaporation of the solvent, which can be kept within limits by using higher-boiling solvents or solvent mixtures. To this extent, significantly longer immobilization times are achieved in this way, so that the printed fluid layer in any case develops low surface tension without any special technical method-related measures under normal ambient conditions, and the modulations subside, before the layer solidifies.

It is therefore expedient to set the viscosity of the fluid to be printed with the aforementioned dependencies taken into consideration, such that it is less than or equal to five times in the case of a shear rate of 1 s⁻¹ and preferably less than or equal to twice the viscosity of the fluid in the case of a shear rate of 500 s⁻¹. The viscosity of the printing fluid should in absolute terms lie in the range between 5 and 500 mPas, preferably between 10 and 500 mPas, in the case of an average shear rate of 100 s⁻¹, in order that the fluid can be processed on rotary printing machines, such as for example flexographic printing machines, gravure printing machines.

There are organic solid materials, such as for example that used for the production of so-called OLEDs under the designation PDY 132 from the Merck company in Darmstadt, Germany, also known by the name “Superyellow”, a soluble phenyl-substituted PPV (poly(p-phenylene vinylene)), which though it dissolves in many nonpolar solvents has for its solutions an immobilization time that becomes increasingly shorter than the demodulation time under normal conditions of ambient temperature, pressure and atmosphere, as our tests have shown. In order to produce usable OLEDs from that substance on rotary printing machines without special method-related techniques, it has surprisingly been found that the desired success can be achieved in any case by certain combinations of solvents. For this purpose, two solvents that differ distinctly in their boiling point are mixed, the afore-mentioned shear rate independence of the fluid thereby formed being obtained when there is an appropriately chosen mixing ratio along with suitable concentrations of the solid material in the solvent mixture. For example, a first solvent, which dissolves the solid material well and has a boiling point of between 80° C. and 180° C., preferably between 80° C. and 140° C., can be mixed with a second solvent, the boiling point of which lies between 140° C. and 250° C., while the difference in the boiling temperatures of the two solvents should be at least 10° C. For the aforementioned case of the phenyl-substituted PPV or chemically similar substances for the functional layer, it may therefore be expedient to work with a combination of solvents, the first solvent being chosen from the following groups of solvents

substituted monoaromatics

monocyclic hydrocarbons

substituted monocyclic hydrocarbons

heteroaromatics

substituted heteroaromatics

hetero-monocycles

substituted hetero-monocycles

and the second solvent being selected from the following groups of solvents

polycyclic aromatics

substituted polycyclic aromatics

polycyclic hydrocarbons

substituted polycyclic hydrocarbons

hetero-polycycles

substituted hetero-polycycles.

Specifically when toluene was chosen as the low-boiling solvent from Table 1 and benzothiazole was chosen as the higher-boiling solvent from Table 2, it was expedient to set the relative concentration of the second, higher-boiling solvent to values between 10% and 35% of the printing fluid, and to set the concentration of the solid material PDY132 to a value in the range between 5 gL⁻¹ and 10 gL⁻¹. In this range, the solubility of the solid material PDY132 in the solvent mixture is at a maximum, i.e. the solubility limit is shifted upward in comparison with the solubilities in only one of the two solvents. It is therefore expedient to select the solvents to be combined and their relative concentrations from this aspect. If appropriate, the surface tension of the printing fluid obtained should also be taken into account when selecting the solvent or solvents, since according to formula (1) it also influences the demodulation time. It should therefore be endeavored to increase the surface tension, without putting at risk the wettability of the substrate onto which the fluid is to be printed.

With the above and other features there is also provided, in accordance with the invention, a rotary printing machine for printing functional layers for electronic components, the printing machine comprising:

a printing cylinder for printing in a printing nip a fluid onto a substrate being guided through the printing nip, the fluid containing solvents and a solid material for the functional layer of the electronic component;

a first treatment zone following said printing nip in a substrate transport direction, configured to guide said substrate therethrough and to dry therein the printed-on functional layers at a relatively low evaporation rate of the solvents contained in the printing fluid, or not at all, during a dwell time tᵥ of the substrate;

a second treatment station following said first treatment zone in the substrate transport direction, said second treatment station being a radiation dryer or hot-air dryer or a vacuum chamber;

wherein a dwell time tᵥ of the substrate in or at said first treatment zone is set to correspond substantially to a time (x·tₗₑᵥ) after which differences in thickness in the printed fluid layer have subsided to a residual modulation level that is no longer considered problematic.

Advantageously, the dwell time tᵥ is less than 30 minutes, or less than 10 minutes, and preferably less than 3 minutes.

There is also provided, in accordance with the invention, a printing fluid for the printing of functional layers for electronic components in a rotary printing machine, the printing fluid comprising:

a soluble solid material and at least one solvent in which said solid material is soluble;

wherein a concentration of said solid material (or solid materials) and said at least one solvent or a composition thereof are selected such that the following applies for the printing fluid:

x·tₗₑᵥ<tᵢₘₘ, where x is a number greater than 1;

wherein x·tₗₑᵥ represents a time within which differences in thickness in the printed fluid layer have subsided to a value that no longer adversely affects a functionality of the functional layer, and tᵢₘₘ is a time by which a ratio of a viscosity to a surface tension has reached a critical value, from which no further smoothing of the printed fluid layer takes place.

Other features which are considered as characteristic for the invention are set forth in the appended claims.

Although the invention is illustrated and described herein as embodied in method and device for printing functional layers for electronic components, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIGS. 1A to 1D are schematic sectional side views of a printing process, with FIG. 1A showing the squeegeeing of the ink from the surface of a gravure cylinder, FIG. 1B showing the transfer of the fluid from the gravure cylinder to the substrate, FIG. 1C showing the result after the substrate with the printed-on fluid leaves the printing nip; and FIG. 1D showing the modulations having receded into the sub-micrometer range;

FIGS. 2A to 2C are three graphs showing the dependency of the shear rate from the viscosity in three different concentrations;

FIG. 3 is a graph showing the experimentally determined immobilizing time in dependence on the benzothiazole content;

FIG. 4 is a graph showing the luminance of the printed functional layers; and

FIG. 5 is a schematic diagram showing the primarily important components of a printing machine according to the invention.

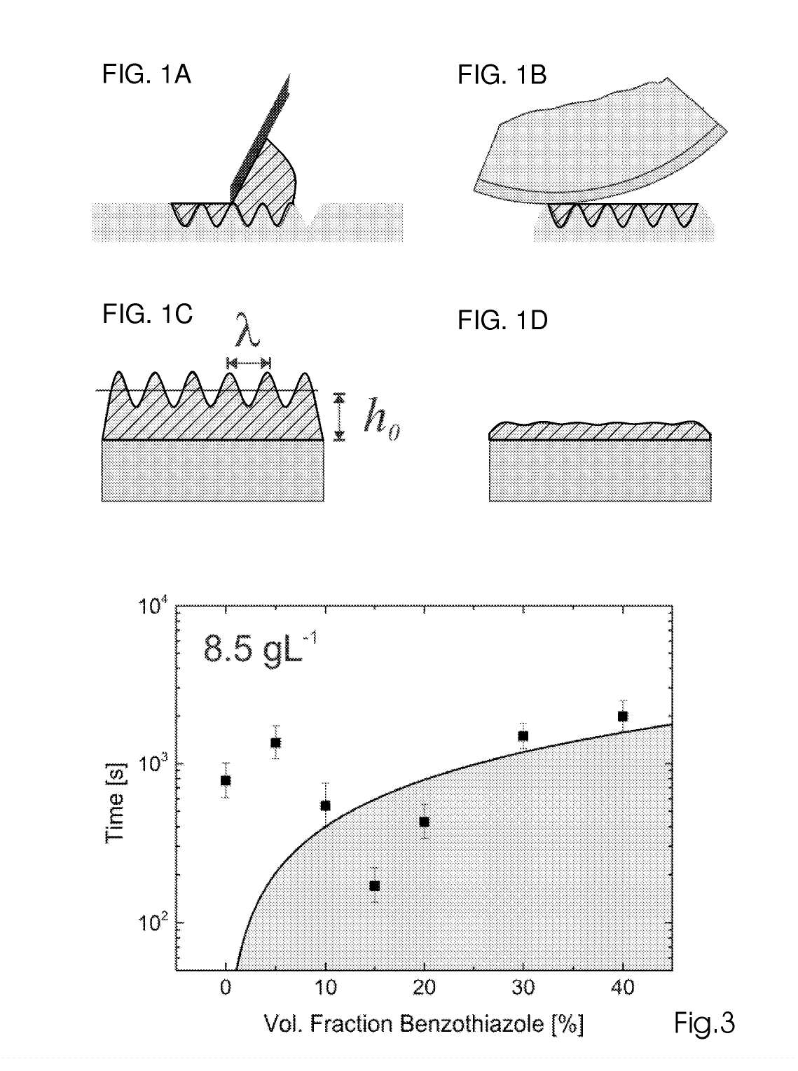

### DETAILED DESCRIPTION OF THE INVENTION

The following description details actual examples and makes reference to the appended drawing.

### EXAMPLE 1

In a first example, PDY132 in three different concentrations (5 gL⁻¹, 8.5 gL⁻¹ and 10 gL⁻¹) was dissolved in a solvent mixture of toluene and benzothiazole, the benzothiazole fraction being increased in stages from 0% through 5%, 15%, 20% and 30% to 40%.

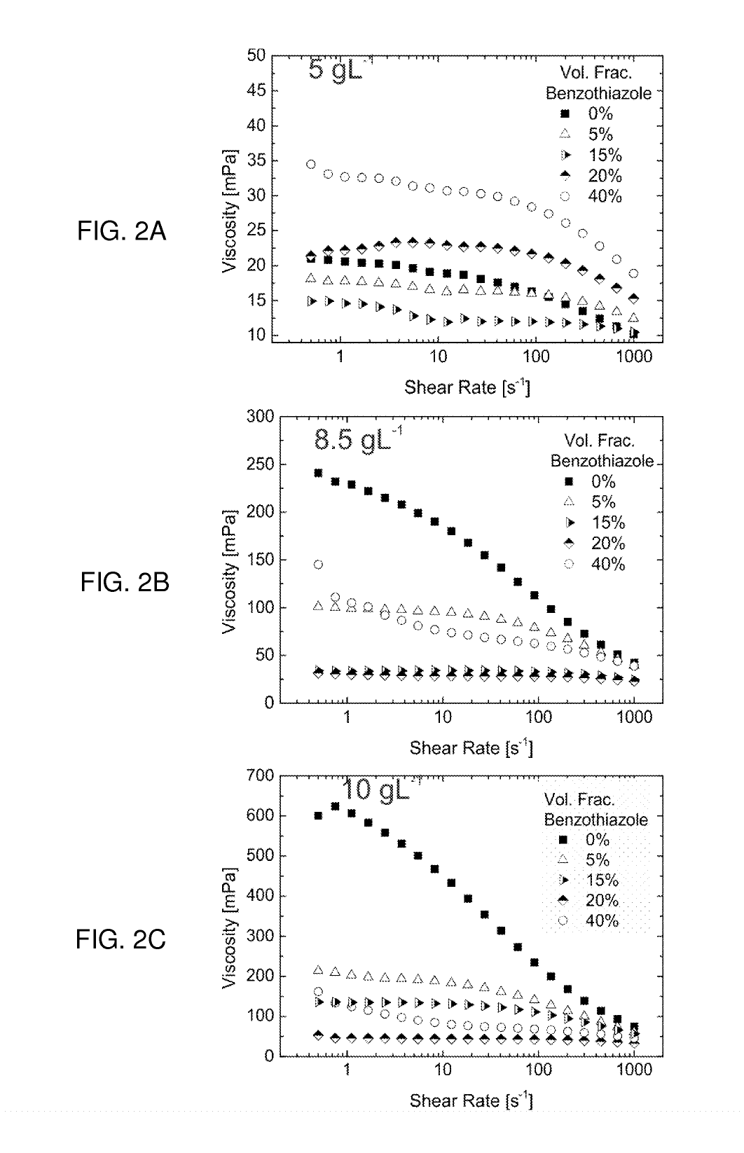

FIGS. 2A to 2C respectively show the measured shear-rate dependence of the viscosity of this fluid for the three concentrations chosen. It can be seen that the viscosity of the fluid in absolute terms and also the change thereof in the range of the shear rate between 0.1 and 1000 s⁻¹ is at the lowest in the case of a mixing ratio of benzothiazole and toluene of between 15% and 20%, to be precise most clearly in FIG. 2B for the henceforth preferred concentration of 8.5 gL⁻¹ of the dissolved solid material. Outside this mixing ratio, the viscosity of the fluid increases and/or displays a highly nonlinear behavior in the case of low shear rates. Mixing ratios in this range between 15% and 20% are therefore particularly well suited for achieving short demodulation times and longer immobilization times.

In FIG. 3, the experimentally determined immobilization time tᵢₘₘ is shown as it is dependent on the fraction of the benzothiazole in the solvent mixture (solid line), and at the same time the demodulation time tₗₑᵥ estimated on the basis of formula (1) of the differently mixed fluids (rectangles with error bars) is plotted. It can be seen that the demodulation time tₗₑᵥ of the layers printed here from the fluids for which the mixing ratio of benzothiazole and toluene lies in the range between approximately 15% and 20% is well below the immobilization time tᵢₘₘ. OLEDs of which the functional layer was printed by the gravure method with a mixing ratio of the solvents of 15% benzothiazole to 85% toluene and a concentration of 8.5 gL⁻¹ PDY132 onto a polyethylene sheet provided with a metal-oxidic electrode structure and then coated with PEDOT: PSS behaved correspondingly, and in accordance with this result. The resultant functional layer had a thickness of ˜75 nm±8 nm and displayed a luminance of 5000 cd m⁻² with a very homogeneous luminance distribution over the entire printed area.

The measured, unsubsided thickness fluctuations of the layers thereby printed were below ±3 nm. On the other hand, layers that were printed with a mixing ratio of only 5% for the benzothiazole fraction only demonstrated luminances of about 500 cd m⁻² with a highly inhomogeneous luminance distribution, in which the unsubsided modulations of the layer thickness were clearly visible as fluctuations in brightness.

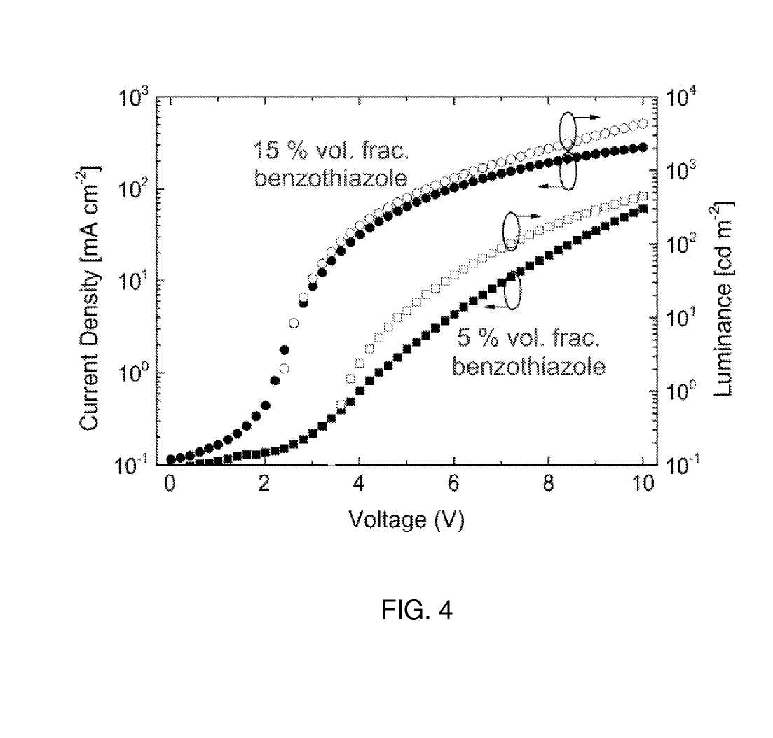

FIG. 4 illustrates the luminance of the functional layers printed with 5% and 15% benzothiazole in the solvent against the electric voltage applied to the layer.

In the example described, a single polymer component, specifically PDY132, was dissolved as the solid material and printed to produce a functional layer. However, it is also possible to print multi-component systems, if appropriate also for functional layers of other types. Such as, for example, the system P3HT: PCBM (poly(3-hexylthiophene: [6.6]-phenyl-C61 butyric acid methyl ester)) for the production of solar cells. In this case, the dried functional layer then consists of a conductive polymer (P3HT) with incorporated nano particles, i.e. the fullerene derivatives PCBM acting as electron acceptors.

### EXAMPLE 2

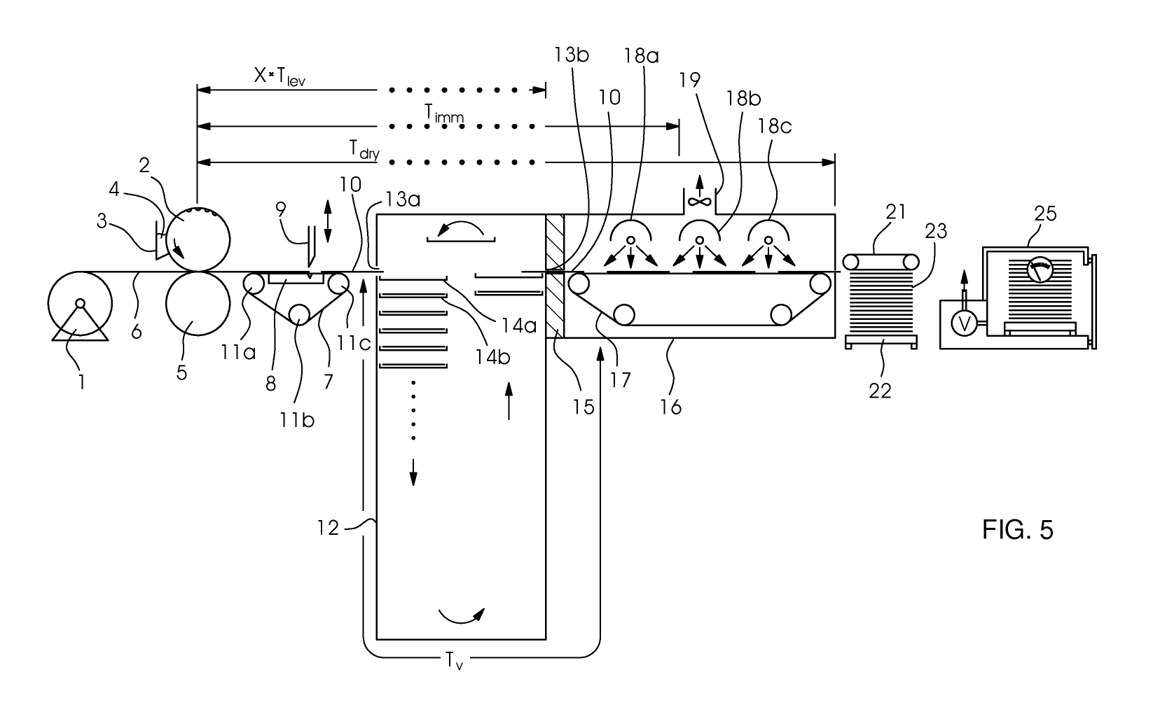

In the above exemplary embodiment it was described how the matching, mentioned in the following patent claims, between the demodulation time and the immobilization time can be achieved by way of the rheology of the fluid to be printed before the printing of the fluid layer. In the following exemplary embodiment 2, it is described how this adaptation can be performed by technical process-related means after the substrate printed with the fluid has passed through the printing nip. Reference is thereby made to FIG. 5, in which the method sequence for the printing of functional layers for electronic components by the gravure method is schematically outlined with reference to the most important components that are expediently used.

A roll winder 1 carries a web of plastic, for example of polyethylene, the surface of which has already been provided in a previous method step with a metal-oxidic electrode structure of indium-tin oxide. This was done, for example, by vapor deposition or sputtering. The oxide was then overprinted with a conductive polymer layer of PEDOT-PSS in a gravure printing method. This substrate web 6 is moved through a gravure cylinder 2 and the impression cylinder lying thereunder. Denoted by 4 is a chambered doctor blade, in which the fluid for the printing of the functional layer, for example a light-emitting polymer, is in the dissolved state with a solvent of which the viscosity has been adapted to the gravure printing method. After passing through the printing nip, the substrate with the gravure printed “images” of the functional layers printed on it lies on a suction belt 7, which is guided over rollers 11a to 11c in an endless loop. In the region between the rollers 11a and 11c, the substrate 6 is guided over a cutting table 8, on which it is separated into individual sheets 10, which subsequently pass through a lock 13a and are pushed into receiving compartments 14a, 14b . . . etc. in a treatment station 12. The treatment station 12 is constructed with a paternoster, in which the compartments 14a, 14b etc. move at a speed that is lower in comparison with the circumferential speed of the gravure cylinder 2, as symbolized by the two arrows, while retaining the horizontal position of the sheets 10, first downward and then upward again in the direction of a second lock 13b. The sheets 10 are discharged through the second lock 13b.

The treatment station 12 has in the interior a solvent atmosphere of the same solvent or solvent mixture that is contained in the fluid 4 or a different solvent that likewise prevents drying. In this way it is achieved that the drying of the functional layers printed onto the substrate sheets 10 is inhibited or, with suitable choice of the partial pressure of the solvent, does not take place at all. The dwell time tᵥ of the separated substrate sheets 10 in the treatment station 12 is in turn chosen such that it corresponds approximately to the demodulation time x·tₗₑᵥ that is required in order for the layer thickness modulations which the printed fluid layer undergoes in the printing nip between the cylinders 2 and 5 to subside to a level that is no longer troublesome, no longer troublesome meaning that remaining residual modulations do not adversely affect the function of the printed layer in the electronic component in which it is to be used.

After being discharged through the lock 13b, the substrate sheets 10 arrive at a second suction belt 17, which is likewise guided as an endless loop in a dryer. The dryer is symbolized here by way of example as a radiation dryer with three infrared light sources 18a, 18b, and 18c. It is alternatively also possible, however, to use hot air, in particular whenever crosslinkable components are admixed with the solvent, UV lamps etc. The solvents outgassing during the drying are extracted by way of an exhaust flue 19.

After the sheets 10 have entered the dryer 16, the functional layers that have been smoothed after passing through the treatment station 12 are consequently immobilized quite quickly on the substrate sheets 10, and then also completely dried through straight away, so that solid layers that no longer undergo any influencing of the homogeneity of the layer thickness during subsequent further treatment are obtained.

After passing through the dryer 16, the substrate sheets 10 arrive in a delivery unit 21, which stacks the substrate sheets 10 on a pallet 22. The stack 23 is subsequently fed to a vacuum chamber 25, in which any remaining residues of solvent by which the function of the printed functional layers could be influenced are extracted.

It is of course also possible to combine the drying in the dryer 16 and the outgassing in the vacuum chamber 25 in one treatment station.

Over the described sequence of the method, the immobilization time tᵢₘₘ or the drying time t_{dry} is separated by technical method-related means from the demodulation time x·tₗₑᵥ, by ensuring that the printed layer modulated by the printing nip has sufficient time to develop low surface tension before the drying commences. OLEDs printed by this method are distinguished by very homogeneous layer thicknesses and high luminances.

1. A method of printing fluid layers for producing functional layers for electronic components, the method comprising:
printing a fluid layer in a printing nip between cylinders of a rotary printing machine;
defining a drying time t_{dry} for the fluid, or an immobilization time tᵢₘₘ between the printing of the fluid layer in the printing nip and an immobilization of the fluid layer;
defining a demodulation time (x·tₗₑᵥ) after which differences in thickness in the fluid layer have subsided after printing to a residual modulation level that is no longer considered problematic; and
adapting the drying time t_{dry}, or the immobilization time tᵢₘₘ, and the demodulation time (x·tₗₑᵥ) to one another such that (x·tₗₑᵥ)<tᵢₘₘ or (x·tₗₑᵥ)<t_{dry}, where x is a number greater than 1.

2. The method according to claim 1, wherein the adapting step at least partially comprises setting or lengthening the drying time t_{dry} or the immobilization time tᵢₘₘ appropriately by technical process-related measures after the printing of the fluid layers onto a substrate.

3. The method according to claim 1, wherein the adapting step at least partially comprises setting or shortening the time tₗₑᵥ and/or the time tᵢₘₘ appropriately by way of a rheology and/or a choice of a surface tension of the fluid to be printed before the printing of the fluid layer onto a substrate.

4. The method according to claim 1, wherein the functional layer is formed by a solid material that is dissolved in a solvent or a solvent mixture and with the solvents forms the fluid to be printed, and the method comprises choosing a concentration of the solid material such that a viscosity of the fluid to be printed has only a low dependence on the shear rate.

5. The method according to claim 4, which comprises setting the viscosity of the fluid to less than or equal to five times the viscosity of the fluid in a case of a shear rate of 1 s⁻¹, or setting the viscosity of the fluid to less than or equal to twice the viscosity of the fluid in a case of a shear rate of 500 s⁻¹.

6. The method according to claim 4, which comprises setting an absolute viscosity of the printing fluid to within a range between 5 and 500 mPas in the case of an average shear rate of 100 s⁻¹ and printing the functional layer by way of a gravure or flexographic printing method.

7. The method according to claim 4, which comprises providing the fluid to be printed for producing the functional layer substantially containing a first solvent, in which the solid material is dissolved, and a second solvent, wherein the second solvent has a higher boiling point in comparison with a boiling point of the first solvent.

8. The method according to claim 7, wherein a boiling temperature of the first solvent lies between 80° C. and 180° C., and a boiling temperature of the second solvent lies between 140° C. and 250° C., and a difference between the boiling temperatures of first and second solvents being at least 10° C.

9. The method according to claim 7, which comprises maintaining a condition according to which the drying time or the time tᵢₘₘ is greater than the time x·tₗₑᵥ at least in part by a ratio of the concentrations between the first and second solvents thus being set in the direction of shortest possible demodulation times tₗₑᵥ and/or longest possible drying time t_{dry} or immobilization time tᵢₘₘ.

10. The method according to claim 1, which comprises, after a substrate with the printed fluid has left the printing nip of the rotary printing machine, feeding the printed functional layers to a first drying zone, in which the functional layer dries with a low rate of evaporation of the solvent or solvent mixture, and, after the demodulation time x·tₗₑᵥ has elapsed, drying the functional layer with at least one dryer selected from the group consisting of a radiation dryer, a hot-air dryer, and a vacuum chamber.

11. The method according to claim 1, which comprises, after a substrate with the printed fluid has left the printing nip of the rotary printing machine, exposing the printed functional layers to a solvent atmosphere in a first treatment zone and, after the demodulation time x·tₗₑᵥ has elapsed, feeding to a dryer and/or a vacuum chamber.

12. The method according to claim 3, which comprises setting the demodulation time tₗₑᵥ of the fluid to be printed to less than 30 minutes.

13. The method according to claim 1, which comprises printing the functional layer onto a substrate that is non-absorbent or does not allow ink to strike through.

14. The method according to claim 13, wherein the substrate has a PEDOT:PPS (poly(3,4-ethylenedioxythiophene):poly(styrene sulfonate)) surface and a main body of PET (polyethylene) provided with a metallic and/or metal-oxidic structure.

15. The method according to claim 1, wherein the functional layer to be printed is a light-emitting polymer layer.

16. The method according to claim 1, which comprises defining the residual modulation level that is no longer considered problematic as being less than ten percent of a layer thickness of the functional layer in a dried state.

17. The method according to claim 16, wherein the residual modulation of the layer thickness of the dried fluid is less than 6 nm.

18. The method according to claim 1, which comprises setting a viscosity of the functional layers to be above 500 mPas in the case of an average shear rate of 100 s⁻¹ and printing the functional layer by an offset printing method.

19. The method according to claim 15, wherein the polymer layer is a soluble phenyl-substituted PPV (poly(p-phenylene vinylene)) or a poly-spirobifluorene or a multi-component system.

20. A rotary printing machine for printing functional layers for electronic components, the printing machine comprising:
a printing cylinder for printing in a printing nip a fluid onto a substrate being guided through the printing nip, the fluid containing solvents and a solid material for the functional layer of the electronic component;
a first treatment zone following said printing nip in a substrate transport direction, configured to guide said substrate therethrough and to dry therein the printed-on functional layers at a relatively low evaporation rate of the solvents contained in the printing fluid, or not at all, during a dwell time tᵥ of the substrate;
a second treatment station following said first treatment zone in the substrate transport direction, said second treatment station being a radiation dryer or hot-air dryer or a vacuum chamber;
wherein a dwell time tᵥ of the substrate in or at said first treatment zone is set to correspond substantially to a time (x·tₗₑᵥ) after which differences in thickness in the printed fluid layer have subsided to a residual modulation level that is no longer considered problematic.

21. The rotary printing machine according to claim 20, wherein the dwell time tᵥ is less than 30 minutes.

22. A printing fluid for the printing of functional layers for electronic components in a rotary printing machine, the printing fluid comprising:
a soluble solid material and at least one solvent in which said solid material is soluble;
wherein a concentration of said solid material (or solid materials) and said at least one solvent or a composition thereof are selected such that the following applies for the printing fluid:
x·tₗₑᵥ<tᵢₘₘ, where x is a number greater than 1;
wherein x·tₗₑᵥ represents a time within which differences in thickness in the printed fluid layer have subsided to a value that no longer adversely affects a functionality of the functional layer, and tᵢₘₘ is a time by which a ratio of a viscosity to a surface tension has reached a critical value, from which no further smoothing of the printed fluid layer takes place.

23. The printing fluid according to claim 22, wherein the concentration of the solid material and the solvent or solvents or relative quantitative ratios thereof are chosen such that, for a shear-rate dependence of the viscosity of the printing fluid formed therefrom, the viscosity is less than or equal to five times in the case of a shear rate of 1 s⁻¹, or less than or equal to twice the viscosity in the case of a shear rate of 500 s⁻¹, and lies between 5 and 500 mPas in the case of an average shear rate of 100 s⁻¹.

24. The printing fluid according to claim 23, wherein said solvent is a mixture of at least two solvents and one of said solvents is selected from the group consisting of:
substituted monoaromatics
monocyclic hydrocarbons
substituted monocyclic hydrocarbons
heteroaromatics
substituted heteroaromatics
hetero-monocycles
substituted hetero-monocycles.

25. The printing fluid according to claim 23, wherein said solvent is a mixture of at least two solvents and one of said solvents is selected from the group consisting of:
polycyclic aromatics
substituted polycyclic aromatics
polycyclic hydrocarbons
substituted polycyclic hydrocarbons
hetero-polycycles
substituted hetero-polycycles.

26. The printing fluid according to claim 22, wherein said solvent or solvents and a relative concentration thereof is chosen in dependence of said solid material to be dissolved for the functional layer such that a solubility limit is increased in comparison with a solubility thereof in the individual said solvents.

27. The printing fluid according to claim 22, wherein said solid material is a soluble polymer or a mixture of a soluble polymer with further soluble substances.
